(19) United States
(12) Patent Application Publication
(10) Pub. No.: US 2003/0042933 A1
(43) Pub. Date: Mar. 6, 2003

(54) Detection of errors in dynamic circuits

(76) Inventors: J. Michael Hill, Ft Collins, CO (US); Jonathan E. Lachman, Fort Collins, CO (US); Clinton H. Parker, Ft. Collins, CO (US)

Correspondence Address: HEWLETT-PACKARD COMPANY, Intellectual Property Administration, P.O. Box 272400, Fort Collins, CO, 80527-2400, US

(21) Appl. No.: 09/947,585

(22) Filed: Sep. 5, 2001

(51) Int. Cl. H03K 19/096

(52) U.S. Cl. 326/95

(57) ABSTRACT

Logic is connected to the outputs of a dynamic logic gate to detect illegal or invalid states. The output of this detection logic sets a state catcher. The output of the state catcher is readable by scan logic so that the occurrence or non-occurrence of the invalid state may be read by test hardware.

### FIELD OF THE INVENTION

The present invention relates generally to integrated circuits, and more particularly, to techniques and circuits for detecting errors in dynamic logic circuits.

### BACKGROUND OF THE INVENTION

Dynamic logic circuits are used in a variety of digital systems and integrated circuits. Some examples of families of dynamic digital logic circuits are “domino logic”, cascode voltage logic (CVL), and “mousetrap logic”. Mousetrap logic gates are described in U.S. Pat. No. 5,208,490 issued to Yetter and is hereby incorporated herein by reference for all that it discloses.

Mousetrap logic envisions three valid vector logic states for each logic path and one invalid vector logic state. Each logic path is comprised of two signals. Two of the valid vector logic states are when only one of the two signals that comprise a logic path is at a logical low. The third valid vector logic state is when both of the signals are at a logical high. The third valid state is envisioned as the “armed” or “waiting to evaluate” state. The invalid logic state is defined as the case when both signals are at a logical low. Whenever this invalid state appears on the output or input of a mousetrap logic gate, it may cause erroneous data to be propagated. Other dynamic logic families may also have similar invalid states.

One problem with mousetrap logic and some other dynamic logic systems is that timing problems, noise, or other “glitches”, can cause an invalid state to appear on the inputs of some dynamic logic gates. When this occurs, the outputs of those logic gates may also propagate invalid or erroneous data. Accordingly, there is a need in the art for a way to detect the occurrence of invalid states on the outputs of dynamic logic gates.

### SUMMARY OF THE INVENTION

Logic is connected to the outputs of a dynamic logic gate to detect illegal or invalid states. The output of this detection logic sets a state catcher. The output of the state catcher is readable by scan logic so that the occurrence or non-occurrence of the invalid state may be read by test hardware.

### BRIEF DESCRIPTION OF THE DRAWINGS

FIG. 1 is a schematic diagram of an example dynamic logic gate with logic attached to detect invalid states on its outputs.

### DETAILED DESCRIPTION OF THE PREFERRED EMBODIMENTS

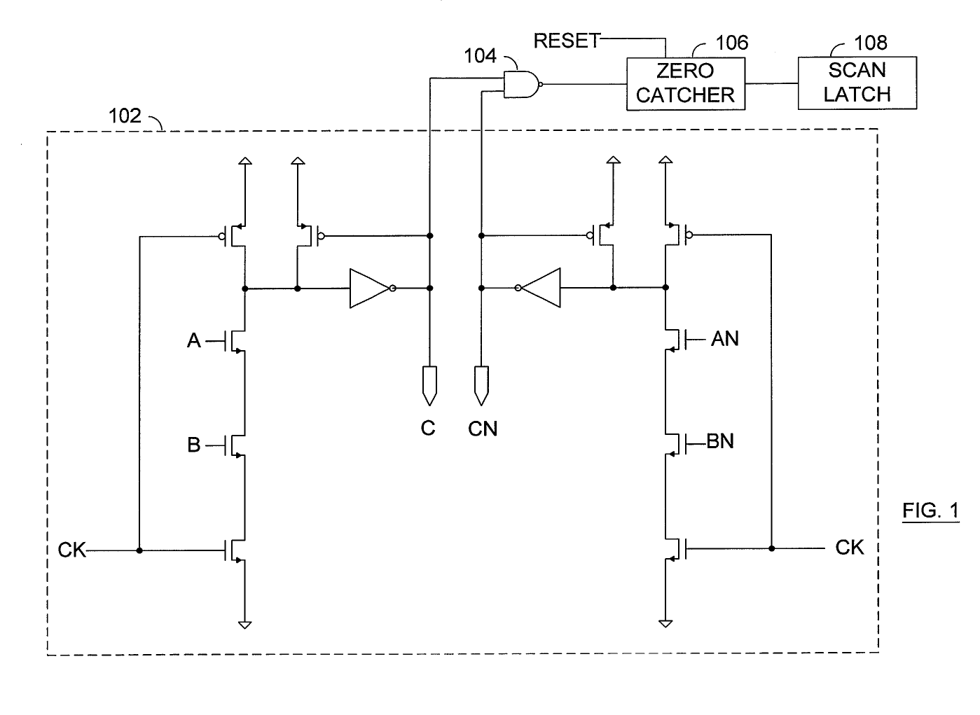

FIG. 1 is a schematic diagram of an example dynamic logic gate with logic attached to detect invalid states on its outputs. In FIG. 1, the circuitry inside box 102 is an example dynamic logic gate. In this case, the gate is an AND gate that takes inputs A and B, their complements (AN and BN), and produces the logical AND of A and B on pair of complementary signals (C and CN) when the clock (CK) is high. Note that this gate is only an example and that the logic function implemented could be any simple or complex logic function with an arbitrary number of inputs and two outputs wherein the outputs have at least one invalid state. Note also that the invalid state for this gate is when both outputs (C and CN) are both high.

The complementary outputs of gate 102 (C and CN) are connected to the inputs of logic function 104. In FIG. 1, the logic function is a NAND gate. A NAND gate is chosen as the logic function in this example because the invalid state for gate 102 is when both outputs are high. Accordingly, when an invalid state appears on the outputs C and CN, the output of logic function 104 will go low. All other times, the output of logic function 104 will remain high. Likewise, an AND gate could have been chosen and the output would be low until an invalid state at which time the output of logic function 104 would go high. Also, should an invalid state be some other combination of outputs (such as all outputs being low) other logic functions based upon the basic logic gates (i.e. NOT, OR, NOR, XOR, etc.) or combinations thereof may be used as the logic function.

The output of logic function 104 is input to a state catcher 106. In this case, the state catcher is a zero catcher. That is, state catcher 106 latches the output of logic function 104 whenever that output goes to a low logic state, even if it is only low for a very brief period of time. There are many known ways to construct a state catcher such as represented by zero catcher 106. For example, an Set-Reset (SR) type latch constructed from cross-coupled NAND gates may be used as a zero catcher. To be used as a zero catcher, the input to be caught would be fed to the Reset input of the SR latch and the Set input would be connected to a reset signal (RESET in FIG. 1). Then, whenever a low appeared on the output of logic function 104, it would reset the SR-type latch “catching” the zero. The latch would remain in this state until it was set again by a reset signal.

The output of state catcher 106 is input to a scan latch 108. The scan latch allows the output of state catcher 108 to be read out of an integrated circuit serially through a scan test port such as is defined by the IEEE 1149.1 (JTAG) boundary-scan standard. Software running on a general purpose computer may then be used to check the data read out of the integrated circuit to see if any invalid states appeared on any of the dynamic logic gates being monitored and provide an indication to a user that an invalid state has occurred and on which logic it occurred on. Additionally, scan latch 108 could be replaced by a latch that is readable via another method such as reading a register or memory location addressable on the chip.

Although a specific embodiment of the invention has been described and illustrated, the invention is not to be limited to the specific forms or arrangements so described and illustrated. The invention is limited only by the claims.

What is claimed is:

1. A circuit, comprising:
a dynamic logic function;
a logic function receiving at least two outputs from said dynamic logic function, said logic function having an output that is in a first logic state for valid states of said at least two outputs and a second logic state for invalid states of said at least two outputs; and,
a state catcher that latches said second logic state when said second logic state is output by said logic function.

2. The circuit of claim 1, further comprising:
a scan latch coupled to said state catcher.

3. A circuit for detecting invalid states, comprising:
a logic function coupled to the outputs of a dynamic logic gate having at least two outputs wherein said at least two outputs have at least one invalid state and said logic function detects said at least one invalid state; and,
a latch coupled to said logic function that latches a logic state indicative of said at least one invalid state having occurred on said at least two outputs.

4. The circuit of claim 3, further comprising:
circuitry coupled to said latch that enables the reading of an output of said latch.

5. A circuit for detecting invalid states output by dynamic logic, comprising:
logic coupled to a set of outputs from said dynamic logic, said logic producing an indication that an invalid state is being output by said dynamic logic;
a latch that catches said indication;
a circuitry for reading said indication into a general purpose computer.

6. The circuit of claim 5, further comprising:
software running on said general purpose computer for processing said indication and producing a notice to a user of said computer that an invalid state has occurred on at least one dynamic logic circuit.

7. A method of detecting invalid logic states on dynamic circuits, comprising:
providing logic coupled to the outputs of dynamic logic that creates an indication that an invalid state has occurred; and,
reading said indication via a port.

8. A method of detecting an invalid logic state on a dynamic logic circuit, comprising:
logically AND'ing a pair of complementary outputs from a dynamic logic circuit wherein logical ones on both of said pair of complementary outputs is an invalid state;
latching an output of said AND function if said output is indicative of said invalid state; and,
providing said latched output to test circuitry that may be read external to an integrated circuit containing said dynamic logic circuit.

9. A circuit that detects an invalid logic state on a dynamic logic circuit, comprising:
an AND logic function connected to a pair of complementary outputs from a dynamic logic circuit wherein logical ones on both of said pair of complementary outputs is an invalid state;
a state catcher that latches an output of said AND logic function when said output is indicative of said invalid state; and,
circuitry for reading the output of said state catcher.
